(19) United States
(12) Patent Application Publication
(10) Pub. No.: US 2015/0053459 A1
(43) Pub. Date: Feb. 26, 2015

(54) PATTERNING OF ELECTRICALLY CONDUCTIVE FILMS

(71) Applicant: Carestream Health, Inc., Rochester, NY (US)

(72) Inventor: Andrew T. Fried, Woodbury, MN (US)

(21) Appl. No.: 14/331,623

(22) Filed: Jul. 15, 2014

Related U.S. Application Data
(60) Provisional application No. 61/867,776, filed on Aug. 20, 2013.

(51) Int. Cl. H05K 3/02; B23K 26/40; B23K 26/36; H05K 1/02; H05K 1/09

(52) U.S. Cl. CPC H05K 3/027; H05K 1/0274; H05K 1/09; B23K 26/365; B23K 26/409; H05K 2203/107
USPC 174/251; 219/121.69

(57) ABSTRACT

Articles and methods of making them, the methods comprising providing a conductive film comprising a first region exhibiting a first conductivity and a second region exhibiting a second conductivity, the first region and the second region each comprising a plurality of conductors, forming a first pattern in the conductive film by exposing the first region of the conductive film to at least a first beam of radiation along a first path having at least one first shape comprising at least one curve, where, after irradiating the first region of the conductive film, the first region of the conductive film exhibits a third conductivity that is less than the second conductivity.

### CROSS REFERENCE TO RELATED APPLICATIONS

This application claims the benefit of U.S. Provisional Patent Application No. 61/867,776, filed Aug. 20, 2013, entitled “LASER PATTERNS OF ELECTRICALLY CONDUCTIVE FILMS,” which is hereby incorporated by reference in its entirety.

### BACKGROUND

WO 2013/095971 to 3M discloses laser patterning of transparent electrical conductor comprising silver nanowires. U.S. Pat. No. 7,355,283 to Chiu et al. discloses forming a rigid wave pattern design on an electrical connector. U.S. Pat. No. 5,711,877 to Gonzalez discloses a filter element etched with a crosshatch design. U.S. Pat. No. 5,192,240 to Komatsu discloses fabricating a microelectronic device that comprises a step of etching. U.S. Patent Publication No. 2012/0103660 to Gupta et al. discloses forming a transparent conductor comprising a nanostructure layer that may be subjected to patterning. U.S. Pat. No. 5,702,565 to Wu et al. discloses laser scribing a pattern in a laminate. U.S. Pat. No. 5,725,787 to Curtin et al. discloses a method of making a light-emitting device that includes a step of etching. U.S. Pat. No. 5,386,221 to Allen et al. discloses apparatuses and methods for generating circuit patterns on a substrate using a laser. U.S. Pat. No. 4,328,410 to Slivinsky et al. discloses a laser skiving system. U.S. Pat. No. 8,409,771 to Ku et al. discloses a laser pattern mask for patterning a substrate. T. Pothoven, “Laser Patterning of Silver Nanowire,” Information Display, 28(9) 20-24 (2012) (available at http://www.laserod.com/wp-content/uploads/2011/09/ID_AgNW_Article_Sep-2012.pdf) discloses the use of laser patterning of silver nanowires. U.S. Patent Publication No. 2011/0248949 to Chang et al. discloses methods and devices related to reducing the effects of differences in parasitic capacitances in touch screens. U.S. Patent Publication No. 2012/0113047 to Hanauer et al. discloses systems and methods for determining multiple touch events in a multi-touch sensor system. U.S. Pat. No. 8,174,667 to Allemand et al. discloses a method of forming a conductive film comprising a plurality of interconnecting nanostructures. WO 2011/106438 to Cambrios Technologies discloses a method of patterning nanowire-based transparent conductors. U.S. Pat. No. 8,279,194 to Kent et al. discloses electrode configurations for projected capacitive touch screen. U.S. Patent Publication No. 2011/0102361 to Philipp discloses touchscreen electrode configurations.

### SUMMARY

Some embodiments provide methods comprising providing a conductive film comprising a first region exhibiting a first conductivity and a second region exhibiting a second conductivity, each of the first region and the second region comprising a plurality of conductors, forming a first pattern in the conductive film by exposing the first region of the conductive film to at least a first beam of radiation along a first path having a shape comprising a curve, where, after exposing the first region of the conductive film to the at least one first beam of radiation, the first region of the conductive film exhibits a third conductivity that is less than the second conductivity. For the purpose of this application, a path along the surface of a film is said to have a shape comprising a “curve” if it possesses non-zero curvature and continuous first derivatives with respect to direction vectors locally tangent to the surface of the film at each point along some portion of the path. In some embodiments, the path has a shape that is a curve, meaning that it possesses non-zero curvature and continuous first derivatives with respect to direction vectors locally tangent to the surface of the film at each point along the entirety of the path.

In some embodiments, the shape of the first path comprises a plurality of curves. In some embodiments, the shape of the first path comprises a sinusoid. In some embodiments, the shape of the first path comprises a first sinusoid, and further comprising exposing the first region of the conductive film to at least a second beam of radiation along a second path having a shape comprising a second sinusoid, where the first sinusoid intersects with the second sinusoid. In some embodiments, the first sinusoid and second sinusoid are minor-images of each other. In some embodiments, the shape of the first path of the first pattern comprises a plurality of non-periodic curves.

In some embodiments, the first region of the conductive film is exposed to at least a second beam of radiation along a second path having a shape comprising a plurality of non-periodic curves, wherein the first path and the second path intersect in one or more intersections. In some embodiments, the shape of the first path of the first pattern comprises a plurality of non-repeating curves. In some embodiments, the first region of the conductive film is exposed to at least a second beam of radiation along a second path having a shape comprising a plurality of non-repeating curves, wherein the first path and the second path intersect. In some embodiments, the first region of the conductive film is exposed to at least a second beam of radiation along a third path surrounding the first path. In some embodiments, the first region of the conductive film is exposed to at least a third beam of radiation along a third path surrounding the first path and the second path. In some embodiments, the third path is rectangular shape.

In some embodiments, where prior to exposing the first region of the conductive film to the at least one first beam of radiation, the first region exhibits a first preexisting set of optical properties and the second region exhibits a second preexisting set of optical properties, and after exposing the first region of the conductive film to the at least one first beam of radiation, the first region exhibits a first consequent set of optical properties and the second region exhibits a second consequent set of optical properties, the first consequent set of optical properties and the second consequent set of optical properties being substantially identical.

In some embodiments, where the first consequent set of optical properties comprises a first consequent total light transmission and the second consequent set of optical properties comprises a second consequent total light transmission that is substantially identical to the first consequent total light transmission.

In some embodiments, where the first consequent set of optical properties comprises a first consequent haze and the second consequent set of optical properties comprises a second consequent haze that is substantially identical to the first consequent haze.

In some embodiments, where the first consequent set of optical properties comprises a first consequent L* value and the second consequent set of optical properties comprises a second consequent L* value that is substantially identical to the first consequent L* value.

In some embodiments, where the first consequent set of optical properties comprises a first consequent a* value and the second consequent set of optical properties comprises a second consequent a* value that is substantially identical to the first consequent a* value.

In some embodiments, where the first consequent set of optical properties comprises a first consequent b* value and the second consequent set of optical properties comprises a second consequent b* value that is substantially identical to the first consequent b* value.

In some embodiments, where the first consequent set of optical properties comprises a first consequent spectral value and the second consequent set of optical properties comprises a second consequent spectral value that is substantially identical to the first consequent spectral value.

In some embodiments, where the first consequent set of optical properties comprises a first consequent reflectance value and the second consequent set of optical properties comprises a second consequent reflectance value that is substantially identical to the first consequent reflectance value.

In some embodiments, the plurality of conductors comprises a plurality of nanowires. In some embodiments, the radiation is emitted by at least one radiation source comprising at least one ultraviolet (UV) laser. In some embodiments, the radiation is emitted by at least one radiation source comprising at least one infrared (IR) laser. In some embodiments, the radiation source operates with a pulse duration of micro-second time domain. In some embodiments, the radiation source operates with a pulse duration of nano-second time domain. In some embodiments, the radiation source operates with a pulse duration of pico-second time domain. In some embodiments, the radiation source operates with a pulse duration of femto-second time domain.

In some embodiments, an article is provided comprising a conductive film comprising a first region exhibiting a first conductivity and a second region exhibiting a second conductivity greater than the first conductivity, each of the first region and the second region comprising a plurality of conductors, and a pattern disposed in the first region of the conductive film comprising a first path having a shape comprising a curve, where the plurality of conductors in the first region has a first average length and the plurality of conductors in the second region has a second average length, the first average length being less than the second average length.

In some embodiments, the shape of the first path comprises a plurality of curves. In some embodiments, the shape of the first path comprises a sinusoid. In some embodiments, the shape of the first path comprises a first sinusoid, and where the pattern comprises a second path having a shape comprising a second sinusoid, where the first sinusoid intersects with the second sinusoid. In some embodiments, the first sinusoid and second sinusoid are mirror-images of each other. In some embodiments, the shape of the first path of the first pattern comprises a first plurality of non-periodic curves. In some embodiments, the first pattern comprises a second path having a shape comprising a second plurality of non-periodic curves, wherein at least some of the first plurality of non-periodic curves and at least some of the second plurality of non-periodic curves intersect. In some embodiments, the shape of the first path of the first pattern comprises a first plurality of non-repeating curves. In some embodiments, the first pattern comprises a second path having a shape comprising a second plurality of non-repeating curves, wherein at least some of the first plurality of non-repeating curves and at least some of the second plurality of non-repeating curves intersect. In some embodiments, the first pattern comprises a third path surrounding the first path. In some embodiments, the first pattern comprises a third path surrounding the first path and the second path. In some embodiments, the plurality of conductors comprises a plurality of nanowires.

In some embodiments, a system is provided comprising a first conductive film comprising a first region exhibiting a first conductivity and a second region exhibiting a second conductivity, each of the first region and the second region comprising a plurality of conductors, and a pattern disposed in the first region of the first conductive film comprising a first path having a shape comprising a curve, where the second conductivity is greater than the first conductivity; wherein the first conductive film is operable to detect a capacitance.

In further embodiments, the system comprises a second conductive film comprising a first region exhibiting a first conductivity and a second region exhibiting a second conductivity, each of the first region and the second region comprising a plurality of conductors, and a pattern disposed in the first region of the second conductive film comprising a first path having a shape comprising a curve, where the second conductivity is greater than the first conductivity; where the second conductive film is operable to detect a capacitance.

### DESCRIPTION OF FIGURES

FIG. 1 shows an embodiment of an electrically conductive film.

FIG. 2 shows an embodiment of a patterned electrically conductive film.

FIG. 3 shows an embodiment of a process in which a nanowire is separated into nanostructures of smaller lengths.

FIG. 4 shows an embodiment of a pattern in an electrically conductive film.

FIG. 5 shows an embodiment of a sinusoid pattern.

FIG. 6 shows an embodiment of a pattern comprising a composite waveform shape.

FIG. 7 shows an embodiment of a pattern comprising overlapping sinusoids.

FIG. 8 shows an embodiment of a pattern comprising a first path in the shape of an “8” adjacent a second path in the shape of an “8.”

FIG. 9 shows an embodiment of a pattern comprising a first path in the shape of an “8” and a second path in the shape of an “8” in which the 8s are positioned end to end.

FIG. 10 shows an embodiment of a pattern comprising a first path having a shape comprising random combinations of curves.

FIG. 11 shows an embodiment of a pattern comprising a first path and a second path each of which comprises a random combination curves.

FIG. 12 shows an embodiment of a self-capacitance touch system.

FIG. 13 shows an embodiment of a mutual-capacitance touch system.

FIG. 14 shows an embodiment of a capacitance calculation.

### DESCRIPTION

All publications, patents, and patent documents referred to in this document are incorporated by reference herein in their entirety, as though individually incorporated by reference.

U.S. Provisional Patent Application No. 61/867,776, filed Aug. 20, 2013, entitled “LASER PATTERNS OF ELECTRICALLY CONDUCTIVE FILMS,” is hereby incorporated by reference in its entirety.

### Electrically Conductive Films

Electrically conductive film may be patterned using a radiation source, such as, for example, a laser, to form electrically isolated regions of lower conductivity near regions of higher conductivity. Conductivity of regions of the film may be measured using conventional instruments, such as, for example, an eddy current meter or a four-point surface resistance probe. A pattern may comprise a first path having a shape comprising a curve. For the purpose of this application, a path along the surface of a film is said to have a shape comprising a curve if it possesses non-zero curvature and continuous first derivatives with respect to direction vectors locally tangent to the surface of the film at each point along some portion of the path. A pattern that comprises a curve may be invisible to the unaided eye, reduce parasitic capacitance, and increase throughput of forming patterns on electrically conductive films. Such patterns may retain the preexisting optical properties of the electrically conductive film prior to patterning.

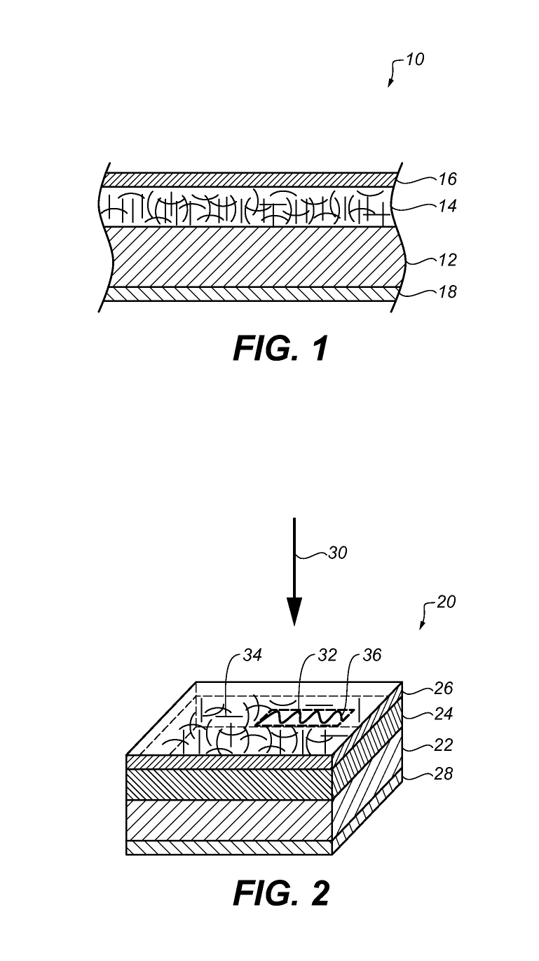

FIG. 1 shows an embodiment of an electrically conductive film 10. The electrically conductive film 10 may comprise a top coat layer 16, an electrically conductive layer 14, a substrate 12, and a hard coat layer 18. The top coat layer may be disposed on the electrically conductive layer 14. The electrically conductive layer 14 may be disposed on the substrate 12. The substrate 12 may be disposed on the hard coat layer 18. In some embodiments, an adhesive (not shown) may be used to bond the hard coat layer 18 to the substrate 12. The electrically conductive layer 14 may comprise a plurality of electrical conductors, such as silver nanowires.

FIG. 2 shows an embodiment of a patterned electrically conductive film 20. The patterned electrically conductive film 20 may be a multi-layer structure that comprises a top coat layer 26, an electrically conductive layer 24, a substrate 22, and a hard coat layer 28. The top coat layer may be disposed on the electrically conductive layer 24. The electrically conductive layer 24 may be disposed on the substrate 22. The substrate 22 may be disposed on the hard coat layer 28. In some embodiments, an adhesive (not shown) may be used to bond the hard coat layer 28 to the substrate 22.

The electrically conductive layer 24 may comprise a plurality of electrical conductors, such as silver nanowires. The electrical conductors may be electrically interconnected to impart conductivity to the electrically conductive layer 24 or the electrically conductive film 20 as a multi-layer structure comprising the electrically conductive layer 24. The electrically conductive film 20 may comprise a first region 32 exhibiting a first conductivity and a second region 34 exhibiting a second conductivity. A region may be defined as an area on the surface of the electrically conductive film 20 that may extend into the layers of the electrically conductive film 20 substantially normal to the surface of the electrically conductive film 20 or the top coat layer 26. For example, a region as an area on the surface of the electrically conductive film 20 may extend into the layers of the electrically conductive film 20 substantially normal to the surface of the electrically conductive film 20 when the area is within 10 degrees of a vector normal to the surface of the electrically conductive film 20 or the top coat layer 26 (e.g. within 9, 8, 7, 6, 5, 4, 3, 2, or 1 degree(s)).

The first region 32 may comprise a first pattern 36. The first pattern 36 may be formed by exposing the first region 32 to one or more beams of radiation from a radiation source 30. After exposing the first region 32 of the electrically conductive film 20 to the radiation 30, the nanowires in the first region 32 may absorb radiation, such that the first region 32 of the electrically conductive film 20 may exhibit a third conductivity that is less than the second conductivity. Without wishing to be bound by theory, it is believed that the radiation absorption by the nanowires may cause the nanowires to separate into smaller nanostructures, thus disrupting the electrical interconnection among nanowires and causing a decrease in conductivity in the region. In some embodiments, the nanostructures may be spaced apart from each other, such that they no longer electrically connect or communicate.

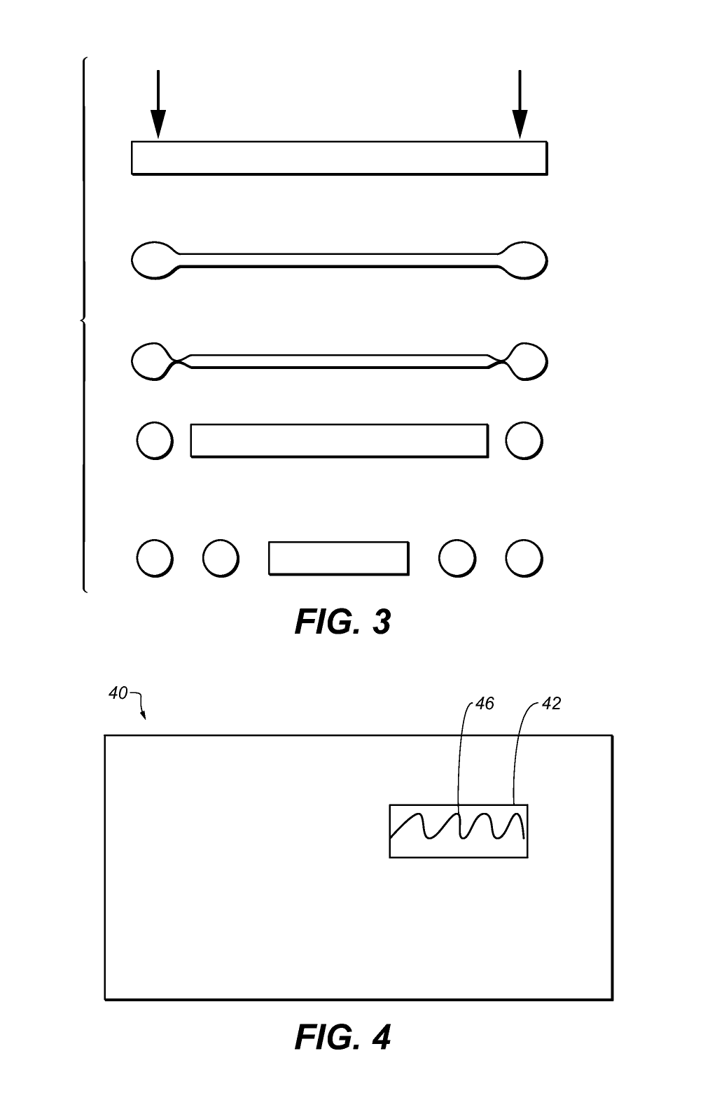

FIG. 3 shows an embodiment of a process in which a nanowire is separated into nanostructures of smaller lengths. When subjected to radiation, the ends of the nanowire may separate from the body of the nanowire in a separation process in which the point of attachment between the ends of the nanowire and the body of the nanowire narrows to the point of separation of the ends of the nanowire from the nanowire body. The separation process may continue with the remaining nanowire. For example, the ends of the remaining nanowire may separate from the body of the remaining nanowire in a separation process in which the point of attachment between the ends of the nanowire and the body of the remaining nanowire narrows to the point of separation of the ends of the nanowire from the body of the remaining nanowire. In some embodiments, the nanowires are separated by being melted into smaller nanostructures. In some embodiments, the separation process may continue after the electrically conductive film is exposed to radiation.

In some embodiments where the first region 32 exhibits a first conductivity less than the second conductivity of the second region 34, the average length of the plurality of electrical conductors in the first region 32 may be less than the average length of the plurality of electrical conductors in the second region 34. In some embodiments, the lengths of the plurality of electrical conductors in the second region 34 may be between about 1 and about 100 micrometers. In some embodiments, the lengths of the plurality of electrical conductors in the second region 34 may be between about 5 and about 30 micrometers. In some embodiments, some of the plurality of electrical conductors in the first region 32 may comprise lengths between about 5 and about 30 micrometers, between about 5 and about 500 nanometers, between about 1 and about 5 micrometers, or between about 1 and about 10 micrometers. For example, the first region may comprise silver nanowires having lengths between about 5 and about 30 micrometers, silver nanospheres having lengths between about 5 and about 500 nanometers, and silver nanorods between about 1 and about 10 micrometers or between about 1 and about 5 micrometers.

In some embodiments where the first region 32 exhibits a first conductivity less than the second conductivity of the second region 34, the aspect ratio of the plurality of electrical conductors in the first region 32 may be less than the average aspect ratio of the plurality of electrical conductors in the second region. For the purposes of this application, the average aspect ratio of an electrical conductor is the end-to-end arc length of the electrical conductor divided by the average diameter of the electrical conductor.

Prior to exposing the first region of the conductive film to the radiation, the first region may comprise a first preexisting number density of electrical conductors and the second region may comprise a second preexisting number density of electrical conductors. After exposing the first region to the radiation, the first region may comprise a first consequent number density of electrical conductors and the second region may comprise a second consequent number density of electrical conductors. In some embodiments, the first consequent number density may be greater than the first preexisting number density. In some embodiments, the first preexisting number density and the second preexisting number density may be substantially identical. In some embodiments, the first consequent number density may be greater than the second preexisting number density. In some embodiments, the first consequent number density may be greater than the second consequent number density. In some embodiments, the second preexisting number density may be substantially identical to the second consequent number density. For the purpose of this application, the number density of electrical conductors is the number of electrical conductors per square meter of film.

In some embodiments, the top coat layer 26 may form the top surface of the electrically conductive film 20. Radiation may be absorbed by the underlying electrically conductive layer 24 through the top coat layer 26. A suitable radiation source, such as, for example, a laser, operated under suitable parameters may be used to expose the nanowires in a first region to one or more beams of radiation to decrease the conductivity in first region without damaging the top coat layer 26, substrate 22, or hard coat layer 28 and without rendering the pattern visible to the unaided eye.

In some embodiments, prior to exposing the first region of the conductive film to the radiation, the first region may exhibit a first preexisting set of optical properties and the second region may exhibit a second preexisting set of optical properties, and after exposing the first region to the radiation, the first region may exhibit a first consequent set of optical properties and the second region may exhibit a second consequent set of optical properties. In some embodiments, the first consequent set of optical properties is substantially identical to the second consequent set of optical properties. In some embodiments, the first preexisting set of optical properties is substantially identical to the first consequent set of optical properties. In some embodiments, the first preexisting set of optical properties is substantially identical to the second preexisting set of optical properties. In some embodiments, the first preexisting set of optical properties is substantially identical to the second consequent set of optical properties. In some embodiments, the first preexisting set of optical properties is substantially identical to the second preexisting set of optical properties and the second consequent set of optical properties. For the purpose of this application, the term “substantially identical” indicates differences that are not discernible to the unaided eye.

Such a first preexisting set of optical properties may, for example, comprise one or more of a first preexisting total light transmission, a first preexisting haze, a first preexisting reflectance value, a first preexisting spectral value, a first preexisting L* value, a first preexisting a* value, or a first preexisting b* value. Such a second preexisting set of optical properties may, for example, comprise one or more of a second preexisting total light transmission, a second preexisting haze, a second preexisting reflectance value, a second preexisting spectral value, a second preexisting L* value, a second preexisting a* value, or a second preexisting b* value. Such a first consequent set of optical properties may, for example, comprise one or more of a first consequent total light transmission, a first consequent haze, a first consequent reflectance value, a first consequent spectral value, a first consequent L* value, a first consequent a* value, or a first consequent b* value. Such a second consequent set of optical properties may, for example, comprise one or more of a second consequent total light transmission, a second consequent haze, a second consequent reflectance value, a second consequent spectral value, a second consequent L* value, a second consequent a* value, or a second consequent b* value. For the purpose of this application, “substantially similar optical appearance” indicates that differences in total light transmission, haze, L*, a*, and b* that are not discernible to the unaided eye. The L* value, a* value, and b* value are part of the Commission Internationale de l'Eclairage (CIE) system of describing the color of an object. For example, the preexisting set of optical properties may differ from the consequent set of optical properties by less than 1%.

In at least some embodiments, the radiation source may be a laser, such as an ultraviolet (UV) laser or an infrared (IR) laser. The laser may be a pulsed or continuous wave laser. In cases where a pulsed laser is used, the pulse duration of the laser may be in the micro-, nano-, pico-, or femtosecond time domain. The laser may be a solid-state laser, such as a diode-pumped solid state laser, a semiconductor laser, or a fiber laser. In some embodiments, the electrically conductive film 20 is irradiated with a pulsed UV laser.

### Patterning Along Paths Comprising Curves

FIGS. 2 and 4 show embodiments of an electrically conductive film comprising at least one pattern in at least one region. In some embodiments, the at least one pattern may be formed in the conductive film by irradiating the at least one region along at least one path. In some embodiments, the at least one region comprising the at least one pattern may exhibit a conductivity that is less than the conductivity of non-irradiated regions.

As shown in FIG. 2, a first pattern 36 may be disposed in the first region 32 of the conductive film 20. As shown, the first pattern 36 may comprise a first path having a shape comprising a curve. For the purpose of this application, a path along the surface of a film is said to have a shape comprising a “curve” if it possesses non-zero curvature and continuous first derivatives with respect to direction vectors locally tangent to the surface of the film at each point along some portion of the path.

In some embodiments, the first pattern 36 may comprise a first path having a shape comprising a plurality of curves or a wavy line or a waveform, such as a sinusoid (as shown). As shown in FIG. 4, a first pattern 46 may be disposed in the first region 42 of the conductive film 40. In some embodiments, the first pattern 46 may comprise a first path and a third path surrounding the first path. In some embodiments, the third path may have a shape comprising a rectangle.

In some embodiments, the shape of the at least one path of the at least one pattern comprises at least one curve. In some cases, curved patterns may reduce undesired capacitance, render the electrically conductive film invisible to the unaided human eye, and increase throughput. In reducing undesired capacitance, the curved pattern may have sufficient dimensions, such that the path of the pattern is near or at the perimeter of the desired region of electrical isolation. In some cases, the curved pattern may have a reduced continuity of charge transport in the long dimension of its path. In increasing throughput, the curved pattern may be formed with a single motion of the radiation source. In some cases, curved patterns may have reduced start/stop delays on the order of 500 to 1500 μs as compared to straight lines.

On a complete touch system, a curved pattern may significantly reduce the amount of time required to finish the pattern. In some cases involving patterns comprising straight lines, the radiation source may need to start and stop multiple times (that is, the radiation source may be turned on and off in sync with galvo-mirror movement) so that the radiation source may move to a different location to start a new path. In some cases where scan speed is sufficiently low such that multiple lines may form a polyline, the radiation source may need to slow down at the corners. In some cases involving patterns comprising a single straight line, touch systems with a relatively large surface area (e.g. greater than 20 inches), may exhibit invisibility but increased capacitance because of the fine separation between a conductive region and electrically isolated region. In some cases, curved patterns may be invisible to the unaided human eye because of their lack of sharp corners, such that there may be less spatial frequency variation that may afford a wider range of invisibility. In some cases, patterns comprising sharp corners, such as a rectangle, a square shaped bar and ladder, or diamond, may render the pattern visible to the unaided human eye based on repetitive spatial frequencies.

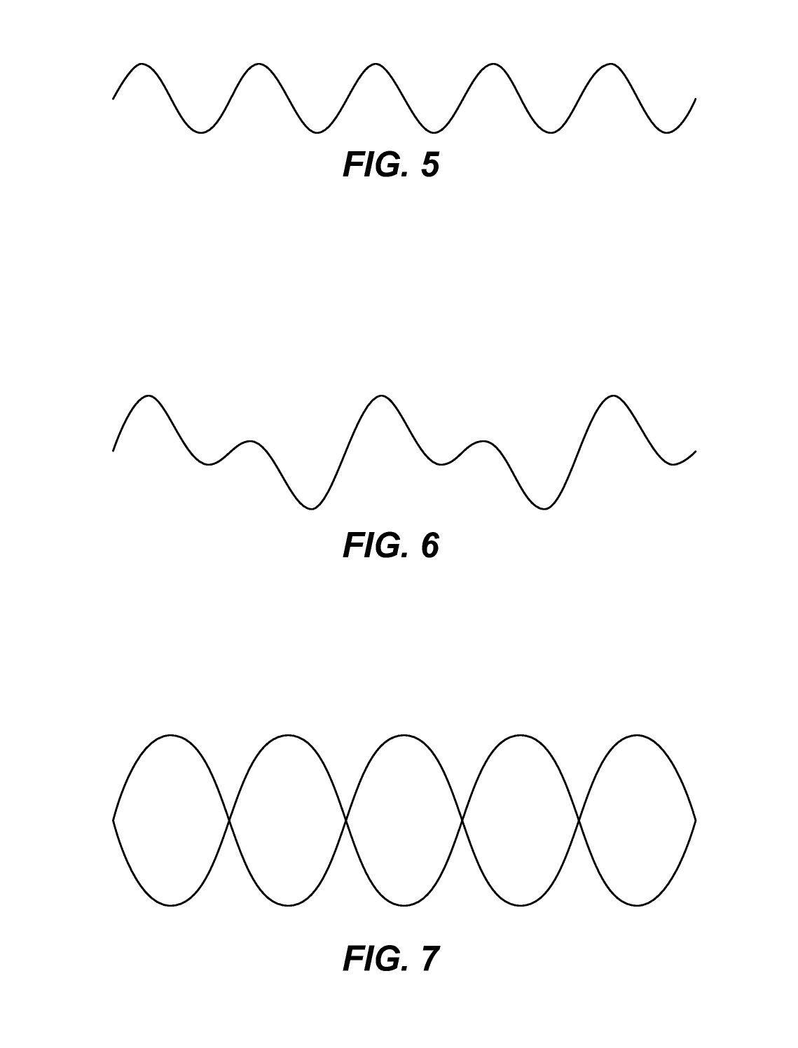

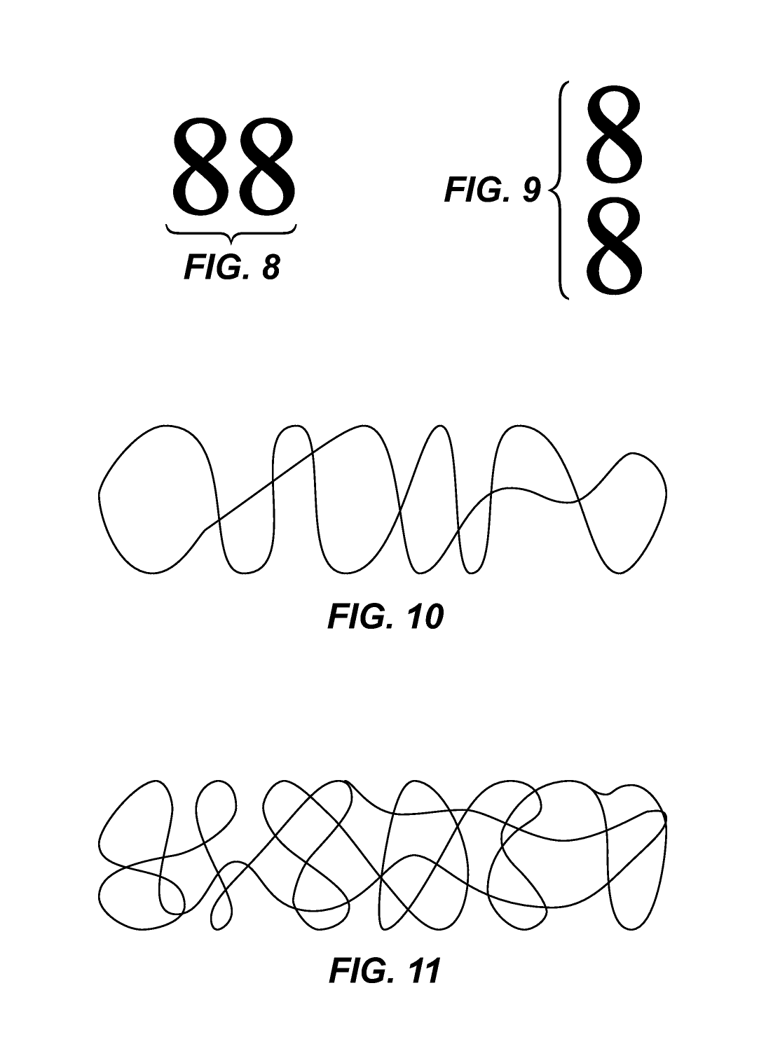

FIGS. 5-11 show embodiments of curved patterns. FIGS. 5-7 show embodiments of waveform patterns comprising regular periodic repeating curves. In such cases, the curves in a waveform may repeat in a regular and periodic manner. FIG. 5 shows an embodiment of a sinusoid pattern. FIG. 6 shows an embodiment of a pattern comprising a composite waveform shape. In some embodiments, the composite waveform shape may be a combination of at least two basis functions, such as sinusoidal waves. FIG. 7 shows an embodiment of a pattern comprising a first sinusoid and a second sinusoid in which the second sinusoid is phase shifted from the first sinusoid by π radians. In such cases, the first sinusoid and the second sinusoid may appear as mirror-images of each other. In some embodiments, a radiation source may form the overlapping sinusoidal pattern in a single path. In some embodiments, the pattern may comprise variable periodic repeating curves.

In some embodiments, the pattern may be along at least one path having an “8” shape. FIGS. 8 and 9 show embodiments of 8-shaped patterns. FIG. 8 shows an embodiment of a pattern along a first path adjacent a second path each of which has an “8” shape to form an “88” shape. FIG. 9 shows an embodiment of a pattern along a first path and a second path each of which has an “8” shape where the 8s are positioned end to end. In some embodiments, the pattern may comprise a single path having an “8” shape. The curves forming the “8” shape may have different radii of curvature.

FIGS. 10 and 11 show embodiments of patterns comprising random combinations of curves. Random combinations of curves may comprise non-repeating curves or non-periodic curves or both. Patterns comprising non-repeating curves may comprise curves of different curvatures. Patterns comprising non-periodic curves may comprise curves of different curvatures or curves having the same curvature that appear at non-regular intervals along a path. FIG. 10 shows an embodiment of a pattern comprising a first path having a shape comprising random combinations of curves. FIG. 11 shows an embodiment of a pattern comprising a first path and a second path each of which comprises a random combination curves. In such cases, the first path and the second path may intersect in one or more intersections.

### Capacitive Touch Systems

An electrically conductive film may be used in a projected capacitive touch system. The touch system may be configured to recognize a touch event through a change in capacitance that results from the touch event. In some embodiments, the touch system may be based on self-capacitance. In some embodiments, the touch system may be based on mutual-capacitance.

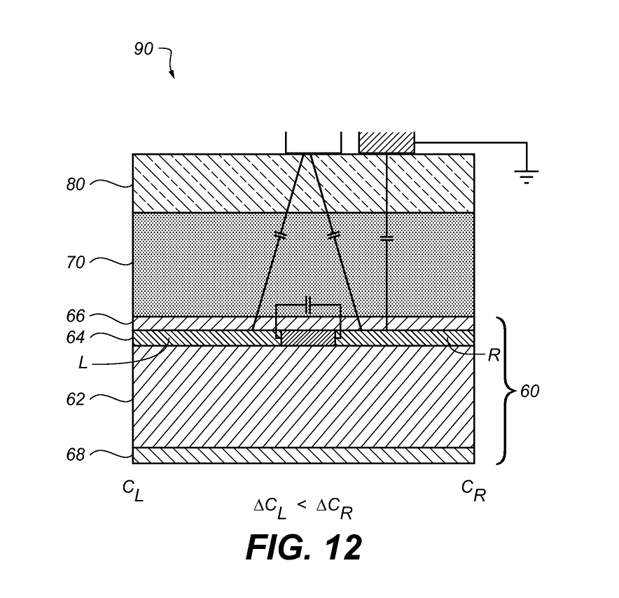

FIG. 12 shows an embodiment of an electrically conductive film 60 as part of a capacitive touch system 90 that uses self-capacitance. The capacitive touch system 90 may comprise an electrically conductive film 60, an adhesive 70, and a surface layer 80. The surface layer 80 may be disposed on the electrically conductive film 60. The electrically conductive film 60 may be bonded to a surface layer 80 by an adhesive 70. The electrically conductive film 60 may comprise a top coat layer 66, an electrically conductive layer 64, a substrate 62, and a hard coat layer 68. The top coat layer 66 may be disposed on the electrically conductive layer 64, which may be disposed on the substrate 62, which may be disposed on the hard coat layer 68.

In a self-capacitance system based touch system, an individual electrode with a self-capacitance to ground can be used to form a touch pixel for detecting touch. For example, the touch system 90 may comprise one or more conductive elements (e.g. silver nanowires in the electrically conductive layer 64) that may present a capacitance to a ground (or virtual ground) plane. As an object, such as a finger tip, approaches the surface layer 80 or the touch pixel, an additional capacitance to ground may be formed between the object and the touch pixel. The additional capacitance to ground may result in a net increase in the self-capacitance, which may be detected and measured by the touch system 90 to determine the position of objects when they touch the touch system 90. Touch systems that rely on self-capacitance may measure an entire row or column of electrodes for capacitive change. Such systems may be limited for touch manipulations that involve more than one touch or simple two touches because it may present positional ambiguity. When the user touches the surface layer in two places, the system may detect touches at two x-coordinates and two y-coordinates, but it may not know which x-coordinate goes with which y-coordinate. This may reduce accuracy and performance of the touch system.

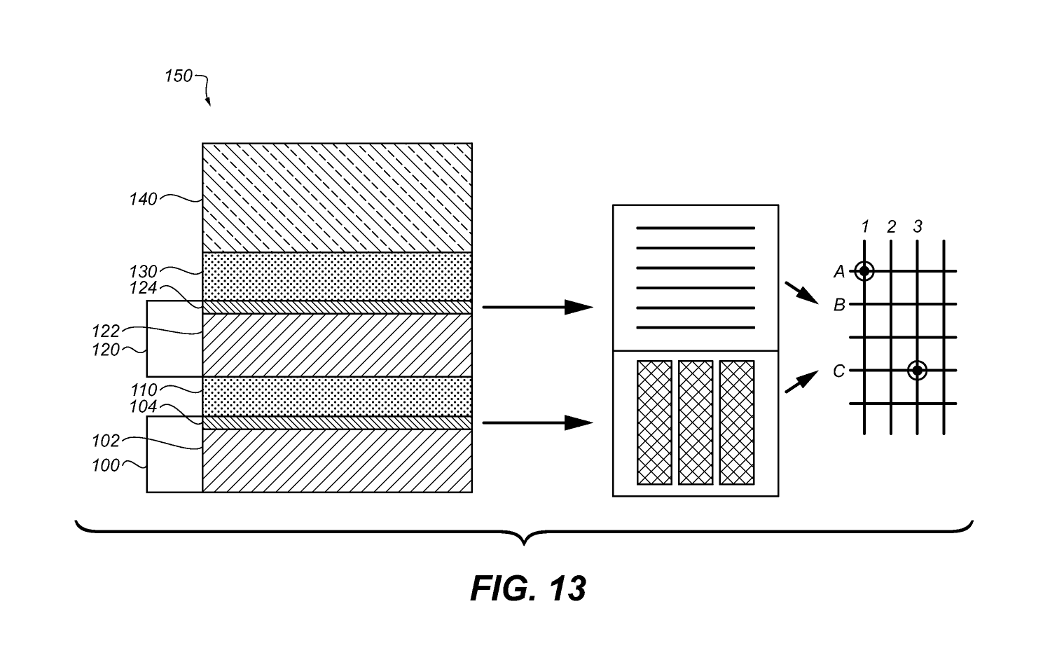

FIG. 13 shows an embodiment of a capacitive touch system 150 using mutual-capacitance comprising two electrically conductive films 104, 124. The capacitive touch system 150 may comprise a first electrically conductive film 100, a first adhesive 110, a second electrically conductive film 120, a second adhesive 130, and a surface layer 140. The surface layer 140 may be disposed on the second electrically conductive film 120, which may be disposed on the first electrically conductive film 100. The first electrically conductive film 100 may be bonded to the second electrically conductive film 120 by a first adhesive 110. The second electrically conductive film 120 may be bonded to the surface layer 140 by a second adhesive 130. The first electrically conductive film 100 may comprise a top coat layer (not shown), an electrically conductive layer 104, a substrate 102, and a hard coat layer (not shown). The top coat layer (not shown) may be disposed on the electrically conductive layer 104, which may be disposed on the substrate 102, which may be disposed on the hard coat layer (not shown). The second electrically conductive film 120 may comprise a top coat layer (not shown), an electrically conductive layer 124, a substrate 122, and a hard coat layer (not shown). The top coat layer (not shown) may be disposed on the electrically conductive layer 124, which may be disposed on the substrate 122, which may be disposed on the hard coat layer (not shown).

As shown in FIG. 13, a mutual-capacitance based touch system may comprise two electrically conductive films 100, 122 which may comprise transmit and receive electrodes. In some embodiments, transmit electrodes may be positioned in rows and receive electrodes may be positioned in columns (e.g. orthogonal). Touch pixels may be positioned at the intersection of the rows and columns. During operation, the rows may be stimulated with an AC waveform and a mutual capacitance may be formed between the row and the column of the touch pixel. As an object, such as a finger, approaches the touch pixel, some of the charge being coupled between the row and column of the touch pixel may instead be coupled onto the object. The reduction in charge coupling across the touch pixel may result in a net decrease in mutual capacitance between the row and the column and a reduction in the AC waveform being coupled across the touch pixel. The reduction in the charge-coupled AC waveform may be detected and measured by the touch system to determine the position of multiple objects when they touch the surface layer of the touch system. For example, a mutual-capacitance system may detect each touch as a specific pair of (x, y) coordinates.

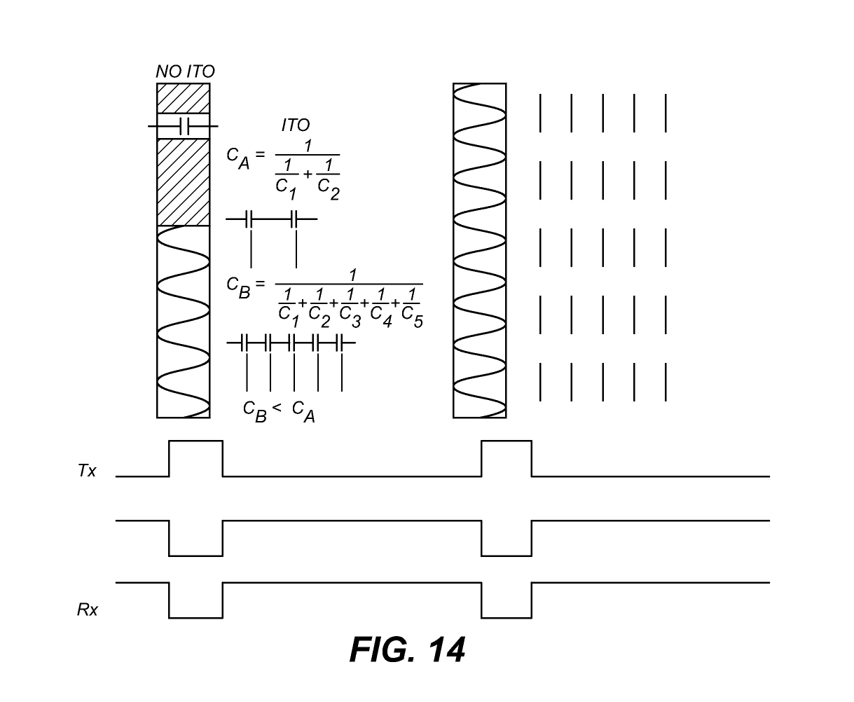

A mutual-capacitance system may be able to accurately determine more complicated touch manipulations than a self-capacitance system. However, the mutual-capacitance system may be more expensive to manufacture than the self-capacitance system because it comprises more than one electrically conductive film. In either system, the conductive elements, such as the silver nanowires in the electrically conductive layer, may form a capacitance to each other. Such capacitance may be undesired, that is, “parasitic” capacitance. Parasitic capacitance may interfere with detection and measurement of capacitance of a touch event. A pattern may be formed in the electrically conductive film to form electrically isolated regions. The pattern may contribute to parasitic capacitance. As shown mathematically in FIG. 14, a pattern comprising more lines may result in less parasitic capacitance than a pattern with a lesser number of lines in the same region. In some cases, a pattern comprising a path having a shape comprising a curve may result in less parasitic capacitance than a pattern comprising a path having a shape comprising a line. In some cases, a pattern comprising a path having a shape comprising random (non-periodic, not repeating) curves may result in less parasitic capacitance than a pattern comprising a path having a shape comprising periodic curves.

In some embodiments, the electrically conductive film may be transparent. In some embodiments, the top coat layer may be a transparent or optically clear material, such as glass. In some embodiments, the electrically conductive layer may comprise conductors, such as carbon nanotubes, metal meshes, graphene, transparent conductive oxide, such as indium tin oxide, or the like. In some embodiments, the adhesive(s) may be a transparent or optically clear material. In some embodiments, the electrically conductive film may be transparent or optically clear. In some embodiments, the top coat layer may comprise a polymer, such as cellulose acetate butyrate. In some embodiments, the hard coat layer may comprise a polymer, such as cellulose acetate butyrate.

### EXEMPLARY EMBODIMENTS

U.S. Provisional Patent Application No. 61/867,776, filed Aug. 20, 2013, entitled “LASER PATTERNS OF ELECTRICALLY CONDUCTIVE FILMS,” which is hereby incorporated by reference in its entirety, disclosed the following 42 non-limiting exemplary embodiments:

A. A method comprising:

providing a conductive film comprising a first region exhibiting a first conductivity and a second region exhibiting a second conductivity, each of the first region and the second region comprising a plurality of conductors,

forming a first pattern in the conductive film by exposing the first region of the conductive film to a radiation source along a first path having a shape comprising a curve,

wherein, after irradiating the first region of the conductive film, the first region of the conductive film exhibits a third conductivity that is less than the second conductivity.

B. The method of embodiment A, wherein the shape of the first path comprises a plurality of curves.
C. The method in either of embodiments A or B, wherein the shape of the first path comprises a sinusoid.
D. The method in any of embodiments A-C, wherein the shape of the first path comprises a first sinusoid, and further comprising exposing the first region of the conductive film to the laser beam along a second path having a shape comprising a second sinusoid, wherein the first sinusoid intersects with the second sinusoid.
E. The method of embodiment D, wherein the first sinusoid and second sinusoid are minor-images of each other.
F. The method in either of embodiments A or B, wherein the shape of the first path of the first pattern comprises a plurality of non-periodic curves.
G. The method of embodiment F, further comprising exposing the first region of the conductive film to the laser beam along a second path having a shape comprising a plurality of non-periodic curves, wherein the first path and the second path intersect.
H. The method in any of embodiments A or B, wherein the shape of the first path of the first pattern comprises a plurality of non-repeating curves.
J. The method of embodiment H, further comprising exposing the first region of the conductive film to the laser beam along a second path having a shape comprising a plurality of non-repeating curves, wherein the first path and the second path intersect.
K. The method in any of embodiments A-J, further comprising exposing the first region of the conductive film to the laser beam along a third path surrounding the first path.
L. The method in any of embodiments D, E, G, or J, further comprising exposing the first region of the conductive film to the laser beam along a third path surrounding the first path and the second path.
M. The method in either of embodiments K or L, wherein the third path is rectangular shape.
N. The method in any of embodiments A-M, wherein the radiation source comprises an IR laser.
P. The method in any of embodiments A-N, wherein prior to exposing the first region of the conductive film to the laser beam, the first region exhibits a first preexisting set of optical properties and the second region exhibits a second preexisting set of optical properties, and after exposing the first region of the conductive film to the laser beam, the first region exhibits a first consequent set of optical properties and the second region exhibits a second consequent set of optical properties, the first consequent set of optical properties and the second consequent set of optical properties being substantially identical.
Q. The method of embodiment P, wherein the first consequent set of optical properties comprises a first consequent total light transmission and the second consequent set of optical properties comprises a second consequent total light transmission that is substantially identical to the first consequent total light transmission.
R. The method of embodiment P, wherein the first consequent set of optical properties comprises a first consequent haze and the second consequent set of optical properties comprises a second consequent haze that is substantially identical to the first consequent haze.
S. The method of embodiment P, wherein the first consequent set of optical properties comprises a first consequent L* value and the second consequent set of optical properties comprises a second consequent L* value that is substantially identical to the first consequent L* value.
T. The method of embodiment P, wherein the first consequent set of optical properties comprises a first consequent a* value and the second consequent set of optical properties comprises a second consequent a* value that is substantially identical to the first consequent a* value.
U. The method of embodiment P, wherein the first consequent set of optical properties comprises a first consequent b* value and the second consequent set of optical properties comprises a second consequent b* value that is substantially identical to the first consequent b* value.
V. The method of embodiment P, wherein the first consequent set of optical properties comprises a first consequent spectral value and the second consequent set of optical properties comprises a second consequent spectral value that is substantially identical to the first consequent spectral value.
W. The method of embodiment P, wherein the first consequent set of optical properties comprises a first consequent reflectance value and the second consequent set of optical properties comprises a second consequent reflectance value that is substantially identical to the first consequent reflectance value.
X. The method in any of embodiments A-W, wherein the radiation source comprises a UV laser.
Y. The method in any of embodiments A-X, wherein the plurality of conductors comprises a plurality of nanowires.
Z. The method in any of embodiments A-Y, wherein the radiation source operates with a pulse duration of micro-second time domain.
AA. The method in any of embodiments A-Z, wherein the radiation source operates with a pulse duration of nano-second time domain.
AB. The method in any of embodiments A-AA, wherein the radiation source operates with a pulse duration of pico-second time domain.
AC. The method in any of embodiments A-AB, wherein the radiation source operates with a pulse duration of femto-second time domain.
AD. A device comprising:

a conductive film comprising a first region exhibiting a first conductivity and a second region exhibiting a second conductivity greater than the first conductivity, each of the first region and the second region comprising a plurality of conductors, and

a pattern disposed in the first region of the conductive film comprising a first path having a shape comprising a curve,

wherein the plurality of conductors in the first region has a first average length and the plurality of conductors in the second region has a second average length, the first average length being less than the second average length.

AE. The device of embodiment AD, wherein the shape of the first path comprises a plurality of curves.
AF. The device in either of embodiments AD or AE, wherein the shape of the first path comprises a sinusoid.
AG. The device in any of embodiments AD-AF, wherein the shape of the first path comprises a first sinusoid, and wherein the pattern comprises a second path having a shape comprising a second sinusoid, wherein the first sinusoid intersects with the second sinusoid.
AH. The device of embodiment AG, wherein the first sinusoid and second sinusoid are mirror-images of each other.
AJ. The device in either of embodiments AD or AE, wherein the shape of the first path of the first pattern comprises a plurality of non-periodic curves.
AK. The device of embodiment AD, wherein the first pattern comprises a second path having a shape comprising a plurality of non-periodic curves, wherein the first path and the second path intersect.
AL. The device in either of embodiments AD or AE, wherein the shape of the first path of the first pattern comprises a plurality of non-repeating curves.
AM. The device of either of embodiments AD or AE, wherein the first pattern comprises a second path having a shape comprising a plurality of non-repeating curves, wherein the first path and the second path intersect.
AN. The device in any of embodiments AD-AM, wherein the first pattern comprises a third path surrounding the first path.
AP. The device in any of embodiment AN, wherein the third path is rectangular shape.
AQ. The device in any of embodiments AD-AP, wherein the third path is circular in shape.
AR. The device in any of embodiments AD-AQ, wherein the plurality of conductors comprises a plurality of nanowires.
AS. A device comprising:

a conductive film comprising a first region exhibiting a first conductivity and a second region exhibiting a second conductivity, each of the first region and the second region comprising a plurality of conductors, and

a pattern disposed in the first region of the conductive film comprising a first path having a shape comprising a curve,

wherein the second conductivity is greater than the first conductivity.

AT. A system comprising:

a first conductive film comprising a first region exhibiting a first conductivity and a second region, each of the first region and the second region comprising a plurality of conductors, and

a pattern disposed in the first region of the first conductive film comprising a first path having a shape comprising a curve,

wherein the second conductivity is greater than the first conductivity; wherein the first conductive film is operable to:

detect a change in capacitance.

### EXAMPLES

### Example 1

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a shape, such as a rectangle, is etched into the silver nanowire layer. The space within the shape is not patterned. Electrical resistance, transmission, reflection, haze, L*, a*, b*, spectral value, reflectance are measured and calculated. The sample is analyzed using scanning electron microscope (SEM).

### Example 2

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a sinusoid is etched into a region in the silver nanowire layer. Electrical resistance, transmission, reflection, haze, L*, a*, b*, spectral value, reflectance are measured and calculated. The sample is analyzed using scanning electron microscope (SEM).

### Example 3

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a border, such as a rectangle, and a sinusoid within the border are etched into the silver nanowire layer. Electrical resistance, transmission, reflection, haze, L*, a*, b*, spectral value, reflectance are measured and calculated. The sample is analyzed using scanning electron microscope (SEM).

### Example 4

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a pattern of overlapping sinusoids is etched into a region in the silver nanowire layer. Electrical resistance, transmission, reflection, haze, L*, a*, b*, spectral value, reflectance are measured and calculated. The sample is analyzed using scanning electron microscope (SEM).

### Example 5

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a border, such as a rectangle, and overlapping sinusoids within the border are etched into the silver nanowire layer. Electrical resistance, transmission, reflection, haze, L*, a*, b*, spectral value, reflectance are measured and calculated. The sample is analyzed using scanning electron microscope (SEM).

### Example 6

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, single path of non-periodic curves is etched into a region in the silver nanowire layer. Electrical resistance, transmission, reflection, haze, L*, a*, b*, spectral value, reflectance are measured and calculated. The sample is analyzed using scanning electron microscope (SEM).

### Example 7

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a border, such as a rectangle, and a single path of non-periodic curves within the border are etched into the silver nanowire layer. Electrical resistance, transmission, reflection, haze, L*, a*, b*, spectral value, reflectance are measured and calculated. The sample is analyzed using scanning electron microscope (SEM).

### Example 8

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, two paths of non-periodic curves are etched into a region in the silver nanowire layer. To create the two paths, the laser is used to create a first path and stopped to move to a different position to create a second path. Electrical resistance, transmission, reflection, haze, L*, a*, b*, spectral value, reflectance are measured and calculated. The sample is analyzed using scanning electron microscope (SEM).

### Example 9

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a border, such as a rectangle, and two paths of non-periodic curves within the border are etched into the silver nanowire layer. To create the two paths, the laser is used to create a first path and stopped to move to a different position to create a second path. Electrical resistance, transmission, reflection, haze, L*, a*, b*, spectral value, reflectance are measured and calculated. The sample is analyzed using scanning electron microscope (SEM).

### Example 10

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, two paths of non-periodic curves are etched into a region in the silver nanowire layer. To create the three paths, the laser is used to create a first path and then stopped to move to a different position to create a second path and then stopped again to move to a different position to create third path. Electrical resistance, transmission, reflection, haze, L*, a*, b*, spectral value, reflectance are measured and calculated. The sample is analyzed using scanning electron microscope (SEM).

### Example 11

### Prophetic

A sample of transparent conductive film comprising a silver nanowire layer on a polyethylene terephthalate (PET) substrate between a top coat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a border, such as a rectangle, and two paths of non-periodic curves within the border are etched into the silver nanowire layer. To create the three paths, the laser is used to create a first path and then stopped to move to a different position to create a second path and then stopped again to move to a different position to create third path. Electrical resistance, transmission, reflection, haze, L*, a*, b*, spectral value, reflectance are measured and calculated. The sample is analyzed using scanning electron microscope (SEM).

The invention has been described in detail with reference to specific embodiments, but it will be understood that variations and modifications can be effected within the spirit and scope of the invention. The presently disclosed embodiments are therefore considered in all respects to be illustrative and not restrictive. The scope of the invention is indicated by the claims, and all changes that come within the meaning and range of equivalents thereof are intended to be embraced therein.

What is claimed:

1. A method comprising:
providing a conductive film comprising a first region exhibiting a first conductivity and a second region exhibiting a second conductivity, the first region and the second region each comprising a plurality of conductors,
forming a first pattern in the conductive film by exposing the first region of the conductive film to at least a first beam of radiation along a first path having at least one first shape comprising at least one curve,
wherein, after irradiating the first region of the conductive film, the first region of the conductive film exhibits a third conductivity that is less than the second conductivity.

2. The method according to claim 1, wherein the at least one shape comprises at least one sinusoid.

3. The method according to claim 2, further comprising exposing the first region of the conductive film to at least a second beam of radiation along a second path having at least one second shape comprising a second sinusoid, wherein the first sinusoid and the second sinusoid intersect.

4. The method according to claim 1, wherein the at least one shape comprises a first plurality of non-periodic curves.

5. The method according to claim 4, further comprising exposing the first region of the conductive film to at least a second beam of radiation along a second path having at least one second shape comprising a second plurality of non-periodic curves, wherein at least some of the first plurality of non-periodic curves and at least some of the second plurality of non-periodic curves intersect.

6. The method according to claim 1, wherein the at least one first shape comprises a first plurality of non-repeating curves.

7. The method according to claim 6, further comprising exposing the first region of the conductive film to at least a second beam of radiation along a second path having at least one second shape comprising a second plurality of non-repeating curves, wherein at least some of the first plurality of non-repeating curves and at least some of the second plurality of non-repeating curves intersect.

8. The method according to claim 1, further comprising exposing the first region of the conductive film to at least a second beam of radiation along a third path surrounding the first path.

9. The method according to claim 1, wherein the radiation is emitted by at least one infrared laser or ultraviolet laser.

10. The method according to claim 1, wherein prior to exposing the first region of the conductive film to the at least one first beam of radiation, the first region exhibits a first preexisting set of optical properties and the second region exhibits a second preexisting set of optical properties, and after exposing the first region of the conductive film to the at least one first beam of radiation, the first region exhibits a first consequent set of optical properties and the second region exhibits a second consequent set of optical properties, the first consequent set of optical properties and the second consequent set of optical properties being substantially identical.

11. The method according to claim 10, wherein the first consequent set of optical properties comprises a first consequent total light transmission and the second consequent set of optical properties comprises a second consequent total light transmission that is substantially identical to the first consequent total light transmission.

12. The method according to claim 10, wherein the first consequent set of optical properties comprises a first consequent haze and the second consequent set of optical properties comprises a second consequent haze that is substantially identical to the first consequent haze.

13. The method according to claim 10, wherein the first consequent set of optical properties comprises a first consequent L* value and the second consequent set of optical properties comprises a second consequent L* value that is substantially identical to the first consequent L* value.

14. The method according to claim 10, wherein the first consequent set of optical properties comprises a first consequent a* value and the second consequent set of optical properties comprises a second consequent a* value that is substantially identical to the first consequent a* value.

15. The method according to claim 10, wherein the first consequent set of optical properties comprises a first consequent b* value and the second consequent set of optical properties comprises a second consequent b* value that is substantially identical to the first consequent b* value.

16. The method according to claim 10, wherein the first consequent set of optical properties comprises a first consequent spectral value and the second consequent set of optical properties comprises a second consequent spectral value that is substantially identical to the first consequent spectral value.

17. The method according to claim 10, wherein the first consequent set of optical properties comprises a first consequent reflectance value and the second consequent set of optical properties comprises a second consequent reflectance value that is substantially identical to the first consequent reflectance value.

18. The method according to claim 1, wherein the plurality of conductors comprises a plurality of nanowires.

19. An article comprising:
a conductive film comprising a first region exhibiting a first conductivity and a second region exhibiting a second conductivity greater than the first conductivity, each of the first region and the second region comprising a plurality of nanowires, and
a pattern disposed in the first region of the conductive film comprising a first path having at least one shape comprising at least one curve,
wherein the plurality of nanowires in the first region has a first average length and the plurality of nanowires in the second region has a second average length, the first average length being less than the second average length.

20. An article comprising:
a conductive film comprising a first region exhibiting a first conductivity and a second region exhibiting a second conductivity, each of the first region and the second region comprising a plurality of conductors, and
a pattern disposed in the first region of the conductive film comprising a first path having at least one shape comprising at least one curve,
wherein the second conductivity is greater than the first conductivity.
